(19) United States
(12) Patent Application Publication
(10) Pub. No.: US 2005/0035355 A1
(43) Pub. Date: Feb. 17, 2005

(54) Semiconductor light emitting diode and semiconductor light emitting device

(75) Inventors: Kuniaki Konno, Kanagawa (JP); Takanobu Kamakura, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/879,058

(22) Filed: Jun. 30, 2004

(30) Foreign Application Priority Data
Jul. 1, 2003 (JP) 2003-189314

(51) Int. Cl. H01L 27/15

(52) U.S. Cl. 257/79

(57) ABSTRACT

A semiconductor light emitting diode and a semiconductor light emitting diode are provided. The semiconductor light emitting diode includes a transparent GaP substrate, an InGaAlP based light emitting multi-layer, an ohmic electrode selectively provided on a GaAs contact layer and a light reflecting metal layer which covers the ohmic electrode and the GaAs contact layer. The GaP substrate is bonded directly to the light emitting multi-layer which emits a visible light.

### CROSS-REFERENCE TO RELATED APPLICATIONS

This application is based upon and claimed the benefits of priority from the prior Japanese Patent Application No. 2003-189314, filed on Jul. 1, 2003, the entire contents of which are incorporated herein reference.

### BACKGROUND OF THE INVENTION

This invention relates to a semiconductor light emitting diode and a semiconductor light emitting device, particularly to those having an improved extraction efficiency, maintaining a low contact resistance.

A light emitting diode (LED) emits a spontaneous light by the recombination of electron-holepairs in an active layer when a forward voltage is applied to the p-n junction. Since a light emitting diode has the advantages such as a low consumption current, a long life time, a small size and a light weight, it is widely used in a various kind of display devices and a traffic signal. And in a case of the back light of an automobile a lower consumption power and a higher brightness are required particularly.

In general, a higher internal quantum efficiency and a higher extraction efficiency cause a highly bright light. Herein the internal quantum efficiency is defined as a ratio of an optical output to an input power, and the extraction efficiency is defined as a ratio of an externally extracted light to a emitted light internally. Since a conventional light emitting diode is formed by growing InGaAlP based light emitting layers on a GaAs substrate, there is a problem that an extraction efficiency is reduced due to a visible light absorption in the GaAs substrate. Because the substrate volume is greater than the InGaAlP light emitting layers, it is important to reduce an absorption in the substrate.

GaP is a material which is not absorptive but transparent to a wavelength emitted from the InGaAlP material. Therefore the extraction efficiency can be improved when GaP is used for the substrate. In this structure the emitting light from the InGaAlP based layers propagates toward a bottom surface of GaP substrate and can be extracted through a side surface and the bottom surface of the substrate without the absorption. As a result the extraction efficiency is much improved and hence a brightness of the light emitting diode becomes higher.

### SUMMARY OF THE INVENTION

According to an aspect of the invention, there is provided a semiconductor light emitting diode comprising:
a GaP substrate having a first and a second major surfaces;
a light emitting layer of InGaAlP provided on the first major surface of the substrate;
a contact layer provided on the light emitting layer;
an ohmic electrode selectively provided on the contact layer; and
a light reflecting metal layer which covers the ohmic first electrode and the contact layer.

According to another aspect of the invention, there is provided a semiconductor light emitting diode comprising:
a substrate having a first and a second major surfaces, the substrate being substantially transparent in a first wavelength range;
a light emitting layer provided on the first major surface of the substrate, the light emitting layer emitting a light of the first wavelength range;
a contact layer provided on the light emitting layer;
an ohmic electrode selectively provided on the contact layer; and
a light reflecting metal layer which covers the ohmic first electrode and the contact layer.
   According to an aspect of the invention, there is provided a semiconductor light emitting device comprising:
a GaP substrate having a first and a second major surfaces;
a light emitting layer of InGaAlP provided on the first major surface of the substrate;
a contact layer provided on the light emitting layer;
an ohmic electrode selectively provided on the contact layer;
a light reflecting metal layer which covers the ohmic first electrode and the contact layer;
a first lead frame on which the light reflecting metal layer is mounted; and
a second lead frame with which the second electrode is connected by a bonding wire.

In the specification, “InGaAlP” includes a compound semiconductor which is represented by InₓGa_{y}Al_{1-x-y}P (where 0≦x≦1, 0≦y≦1 and {x+y}≦1).

### BRIEF DESCRIPTION OF THE DRAWINGS

The present invention will be understood more fully from the detailed description given herebelow and from the accompanying drawings of the embodiments of the invention. However, the drawings are not intended to imply limitation of the invention to a specific embodiment, but are for explanation and understanding only.

In the drawings:

FIG. 1A is a cross-sectional view of a light emitting diode according to a first embodiment;

FIG. 1B is a bottom plan view taken along a line A-A′ of FIG. 1A;

FIG. 2 is a diagram for an explanation of an extracted light path;

FIG. 3 shows a relationship between an electrode center position and a relative extraction efficiency;

FIG. 4A is a cross-sectional view explaining a position of the n-side ohmic electrode;

FIG. 4B is a bottom plan view taken along a line A-A′ of FIG. 4A;

FIG. 5 is a cross-sectional view of an InGaAlP based multi-layer provided on a GaAs substrate;

FIG. 6 is a cross-sectional view of a GaP substrate bonded to the InGaAlP based multi-layer provided on the GaAs substrate of FIG. 5;

FIG. 7 is a cross-sectional view of the GaP substrate bonded to the InGaAlP based multi-layer (after the GaAs substrate removal);

FIG. 8 is a cross-sectional view of the bonded wafer having the electrodes on both sides;

FIG. 9 is a plan view taken along a line A-A′;

FIG. 10 is a cross-sectional view of the bonded wafer covered with a light reflector metal;

FIG. 11 is a cross-sectional view of the device before expanding;

FIG. 12 is a cross-sectional view of the device after expanding;

FIG. 13 is a cross-sectional view of the wafer of a half cut dicing;

FIG. 14 is a cross-sectional view of the device to obtain a tapered side device;

FIG. 15 is a cross-section view of the device after expanding;

FIG. 16 is a cross-sectional view of a light emitting device;

FIG. 17 is a cross-sectional view of a light emitting device according to a second embodiment;

FIG. 18 is a cross-sectional view of a light emitting device according to a third embodiment;

FIG. 19 is a cross-sectional view of a light emitting device according to a fourth embodiment;

FIG. 20 is a cross-sectional view of a modified device of the fourth embodiment; and

FIG. 21 is a cross-sectional view of a light emitting device examined by the Inventors.

### DETAILED DESCRIPTION

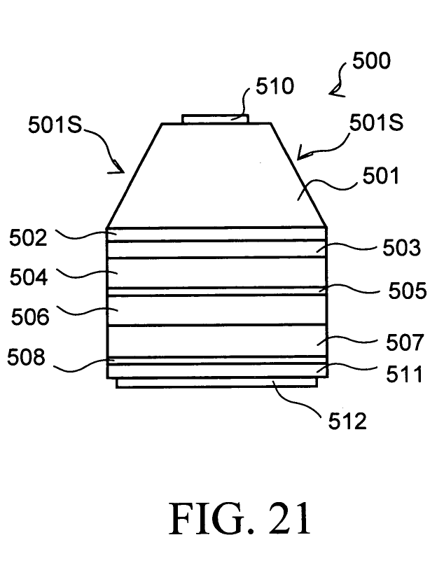

FIG. 21 shows a cross-sectional view of a semiconductor light emitting diode which was examined during the development by the Inventors. This light emitting diode 500 is formed by bonding an InGaAlP multi-layer grown epitaxially on a GaAs substrate directly to a GaP substrate. This technology is disclosed in Japanese Patent Laid-Open No. 11-162985. This structure will be explained hereinafter.

There are provided a p-type GaP substrate 501, a p-type GaP bonding layer 502, a p-type InGaP bonding layer 503, a p-type cladding layer of InAlP 504, a p-type MQW layer of InGaAlP 505, an n-type cladding layer of InAlP 506, an n-type current diffusion layer of InGaAlP 507, an n-type GaAs contact layer 508 and an n-side ohmic electrode 511, in this order. And a p-side ohmic electrode 510 is provided on a surface of the p-type GaP substrate and a solder layer 512 is provided on a surface of the n-side ohmic electrode to obtain a low thermal-resistance die bonding appropriately.

A light from the MQW layer which is an active layer enters into the GaP bonding layer 502 and propagates to the outside through a bottom surface and tapered side surface 501 of the GaP substrate 501 with a higher extraction efficiency. This light emitting diode chip is mounted to a metal lead frame (electrode) of a package or an assembling substrate using the solder layer if necessary. And a p-type ohmic electrode 510 is connected with another electrode of the package by wires. The light emitting diode can operate by applying a voltage between both electrodes. The major disadvantage of the above-mentioned device is a light absorption in the n-side ohmic electrode which includes alloyed layer formed by annealing after an AuGe depositon on the GaAs contact layer. The ohmic layer formed by the annealing can reduce the barrier height (work function) between AuGe and GaAs but causes an increase of the light absorption. Considering that half of the emitted light propagates toward the n-type ohmic electrode 511, this light absorption is a cause of the optical loss which reduces the extraction efficiency.

Referring to drawings, some embodiments of the present invention will now be described in detail.

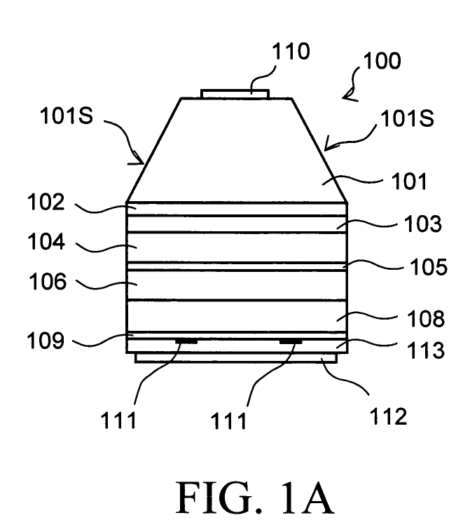

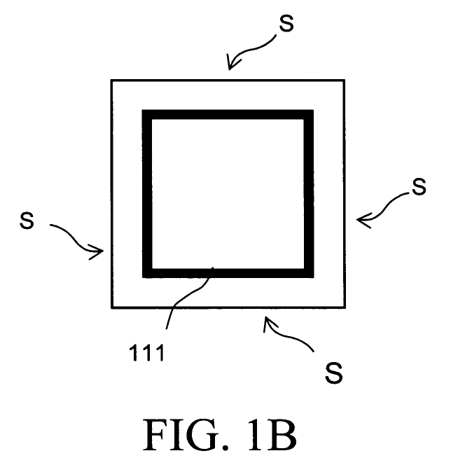

FIG. 1A is a cross-sectional view of the light emitting diode according to a first embodiment of the invention. There are provided a p-type GaP substrate 101, a p-type GaP bonding layer 102, a p-type InGaP bonding layer, a p-type cladding layer of InAlP, a p-type MQW layer of InGaAlP, an n-type cladding layer of InAlP, an n-type current diffusion layer of InGaAlP and an n-type GaAs contact layer, in this order. And an n-side ohmic electrode 111 is disposed partly on a surface of GaAs contact layer 109.

A light reflecting metal layer 113 such as Au and Al is provided on the surface of the n-side electrode 111 and the GaAs contact layer 109, and a solder layer 112 is provided thereon. The n-side ohmic electrode 111 is formed so that an ohmic metal such as AuGe is deposited on the GaAs contact layer 109 and then annealed to obtain an alloyed layer for reducing a barrier height between GaAs and the ohmic metal.

In addition the light reflecting metal layer connected to the ohmic electrode functions as a part of the n-side electrode. Since the light reflecting metal layer does not form an alloy layer, a reflection coefficient of the light reflecting metal layer is higher than that of the n-side electrode at a wavelength emitted from the above-mentioned active layer.

FIG. 1B is a bottom plan view taken along a line A-A′ of FIG. 1A. A pattern of an n-side ohmic electrode is a hollow square shown by a dark area in FIG. 1B. This electrode comprises four stripes parallel to the edges of a light emitting diode apart from the side surface S of the light emitting diode. If an area of the n-side ohmic electrode is as small as possible without an increase of the contact resistance, an area of the light reflector is as greater as possible and it makes possible to reflect the greater light toward the GaP substrate.

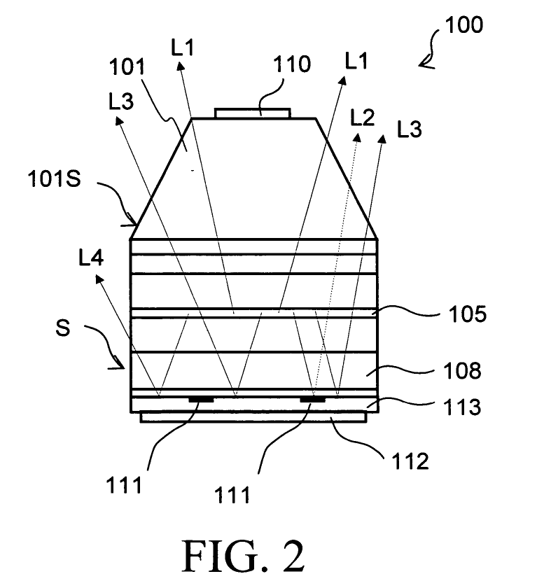

FIG. 2 is a diagram for an explanation of an extracted light path. The light toward the GaP substrate (L1) emitted from the MQW layer of InGaAlP 105 is extracted from the top surface and side surface of the GaP transparent substrate 101 outward. If the side surface 101S of the GaP substrate is tapered, a total reflection can be reduced and hence the higher extraction efficiency is obtained. The incident light upon the n-side ohmic electrode 111 is a part of the light toward the light reflecting metal layer 113 and is absorbed in the alloyed region. After an attenuation due to the absorption the incident light is reflected and extracted outward as a light L2 of FIG. 2.

The incident light L3 upon the light reflecting metal layer is reflected without the attenuation due to a high reflection coefficient of Au and Al, and is extracted from the surface of the GaP substrate. Similarly the incident light L4 is extracted from the surface S of the InGaAlP multi-layer. According to the first embodiment, the light extraction efficiency is drastically improved because the n-side ohmic electrode is provided selectively and the light reflector is provided thereon.

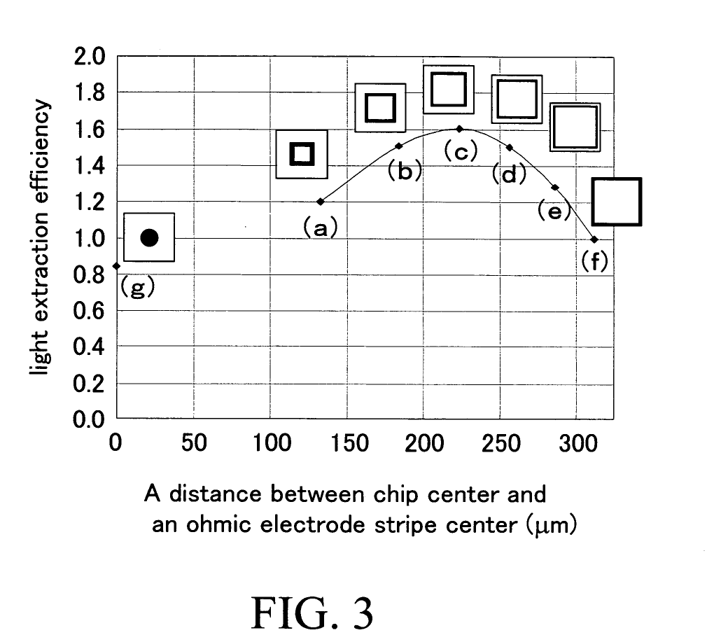

FIG. 3 is a relationship between an ohmic electrode position and light extraction efficiency. X-axis represents a distance between a light emitting diode center and an ohmic electrode stripe center. Y-axis represents light extraction efficiency. The point (a) through (f) corresponds to each electrode configuration, respectively. A case (f) shows a diode of which an ohmic electrode is provided so that an outer edge of the electrode coincides with the edge of the diode in a bottom plan view.

A light extraction efficiency of a point (f) is defined as 1.0 in the Y-axis. When an area of the ohmic electrode is too small, a contact resistance increases and hence a light emitting characteristic is degraded. Therefore the ohmic contact area is 15% of the light emitting diode surface. In addition, a case (g) shows a diode having a circular n-side ohmic electrode of which an area is 15% of the light emitting diode surface.

A shape of the light emitting diode is a square having a 750 μm edge. A p-side electrode 110 provided on a surface of the GaP substrate has a circular shape and its area is 30% of the light emitting diode surface. When a position of an n-side ohmic electrode is varies from a center of the light emitting diode to the outside, the relative extraction efficiency increases and reaches a maximum at a point (c). When the position of the electrode approaches to the outside further, the relative extraction efficiency decreases again. A circular electrode diode (g) shows a lower extraction efficiency of 0.82. On the other hand, when an n-side ohmic electrode is provided on an entire surface of the light emitting diode, the relative extraction efficiency becomes 1.2 approximately. Therefore it is concluded that the light emitting diodes of (a) through (e) have the higher extraction efficiency compared to the 100% ohmic electrode diode mentioned above.

The reason why these results are obtained is explained below, qualitatively. If an n-type ohmic electrode is provided in a central region, the light intensity has a peak near a central region according to an injected current distribution. Since a light intensity has a maximum under the p-type electrode as shown in FIG. 2, the extraction efficiency decreases because of an interruption by the p-type electrode.

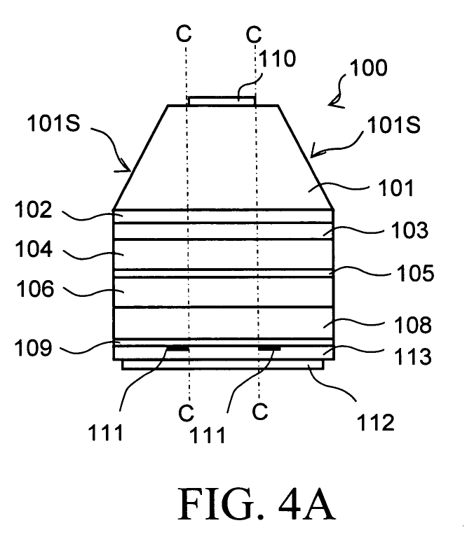

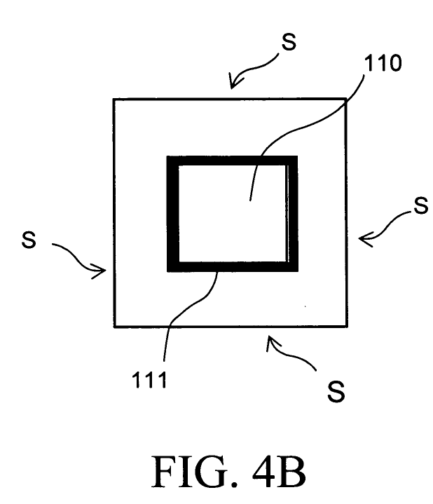

When a p-type ohmic electrode approaches to the outside between (a) and (c), the light interruption by the p-type electrode is reduced and hence the extraction efficiency becomes higher. However when the p-side electrode approaches to the outside further, the current injected from the n-side ohmic electrode can not diffuse sufficiently due to the side surface and the extraction efficiency decreases again. It is desirable that an inner edge of the n-side ohmic electrode 111 coincides with the outer edge of the p-side electrode 110, approximately, as shown by the lines C-C in a cross-sectional view of FIG. 4A.

An area ratio of an n-type ohmic electrode and its position is not restricted to the above-mentioned example, but may be determined by considering the structural parameters of the light emitting diode such as a diode height, a diode junction area, a p-type electrode area and position, a Gap substrate thickness, a current diffusion layer thickness and so on.

A method for manufacturing the light emitting device will be now described as follows. FIGS. 5 through 7 show the substrate bonding steps. FIG. 5 is a cross-sectional view. There is provided a semiconductor multi-layer 200 on an n-type GaAs substrate 300 by using MOCVD (metal-organic chemical vapor deposition) technique. The semiconductor multi-layer 200 includes ann-type GaAs contact layer 109, ann-type current diffusion layer of InGaAlP, an n-type cladding layer of InAlP, a p-type MQW layer of InGaAlP, a p-type cladding layer of InAlP and a p-type InGaP bonding layer.

One example for growing an n-type cladding layer 106 is explained below. PH₃ and Metal-organic gases such as trimethylgallium (TMG), trimethylindium (TMI) and trimethylaluminum (TMA), along with a hydrogen carrier gas and a SiH₄ n-type doping gas are introduced into a reactor.

An n-type cladding layer of In_{0.49} (Ga_{0.3}Al_{0.7})_{0.5}P is grown at a temperature between 500 to 900° C. epitaxially having a thickness of 0.5 μm and a carrier concentration of 1.0×10¹⁶ to 1.0×10¹⁹/cm³. Dimethylzinc may be used for a p-type doping gas. Subsequently a GaP substrate 101 is directly bonded to the surface of the semiconductor multi-layer 200. Before the bonding, a Zn doped GaP bonding layer 102 is grown with a thickness of 1 nm to 1 μm by using MOCVD.

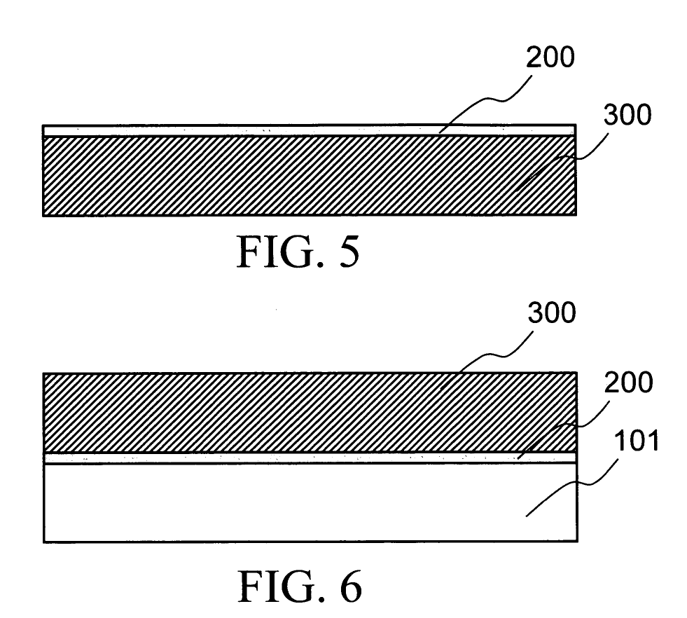

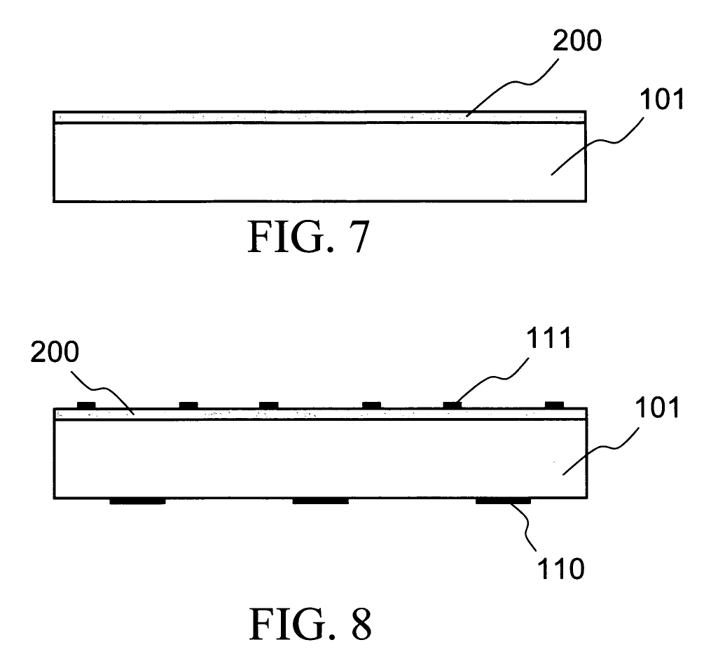

A structure shown in FIG. 6 is obtained by bonding both surfaces of the multi-layer 200 and the GaP bonding layer 102 under a pressure of 0.1 to 10 kg/cm² at 700° C. Subsequently a GaAs substrate is removed by a mixed solution of H₂O₂ and H₂SO₄ for 10 to 60 minutes as shown in FIG. 7.

FIGS. 8 through 12 show the steps for forming the light emitting diode chip. A p-side electrode 110 is formed on a surface of the GaP substrate and an n-side ohmic electrode is formed on a surface of the n-type contact layer 109 by a metal deposition and a pattering process, respectively.

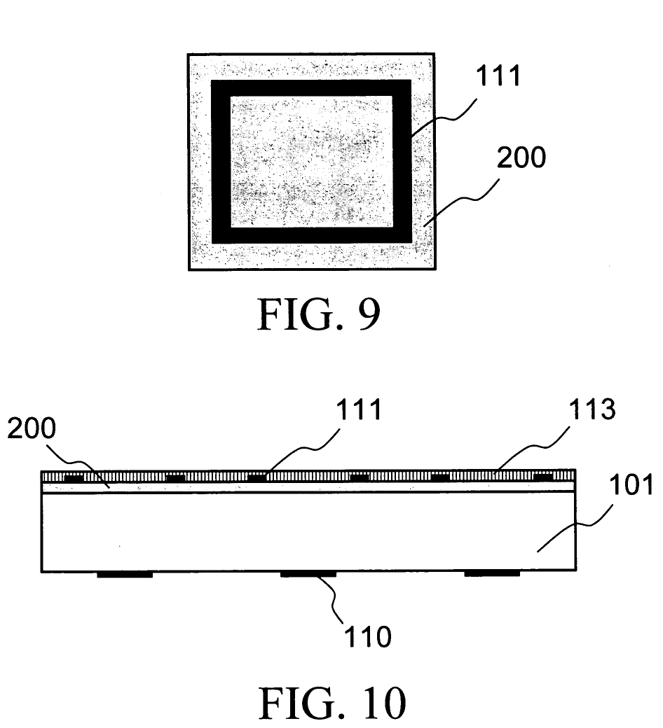

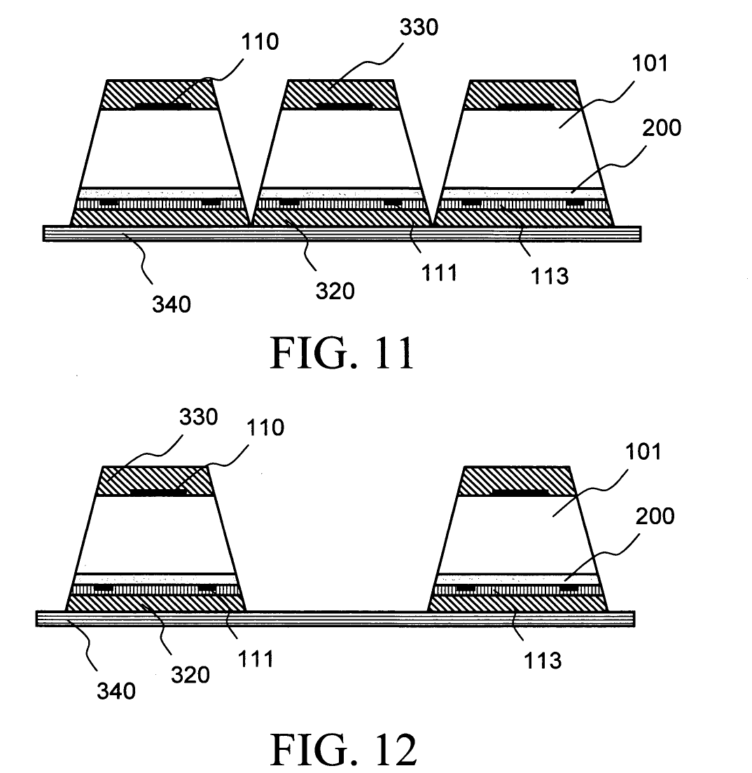

An n-side ohmic electrode 111 has a hollow square shape patterned selectively so that the electrode is located apart from the side surface of the diode, as shown in FIG. 9. Subsequently both surface of the bonded wafer are covered with the photoresists 320 and 330 for a surface protection as shown in FIG. 10. A surface of a photoresist 320 which is provided on the surface of the n-side electrode is bonded to a tape 340 and then the chips are separated by dicing, as shown in FIG. 11.

If the angle of dicing blade edge in a cross-section is selected appropriately, the side surface of the GaP substrate can be tapered. FIG. 12 is a cross-sectional view after expanding horizontally for the separation of the chips. The damage layer of the side surface caused by dicing can be removed by etching using a mixed solution of H₂O₂, H₂O and HCl for 10 minutes or more.

If the chip is immersed in a HF solution for 5 minutes, fine inequalities are formed on the GaP side surface with a few μm height. These inequalities reduce the entire reflection on the side surface and hence the extraction efficiency becomes higher. In FIG. 12 the side surface of the GaP substrate is tapered entirely, but the side surface may be tapered partly.

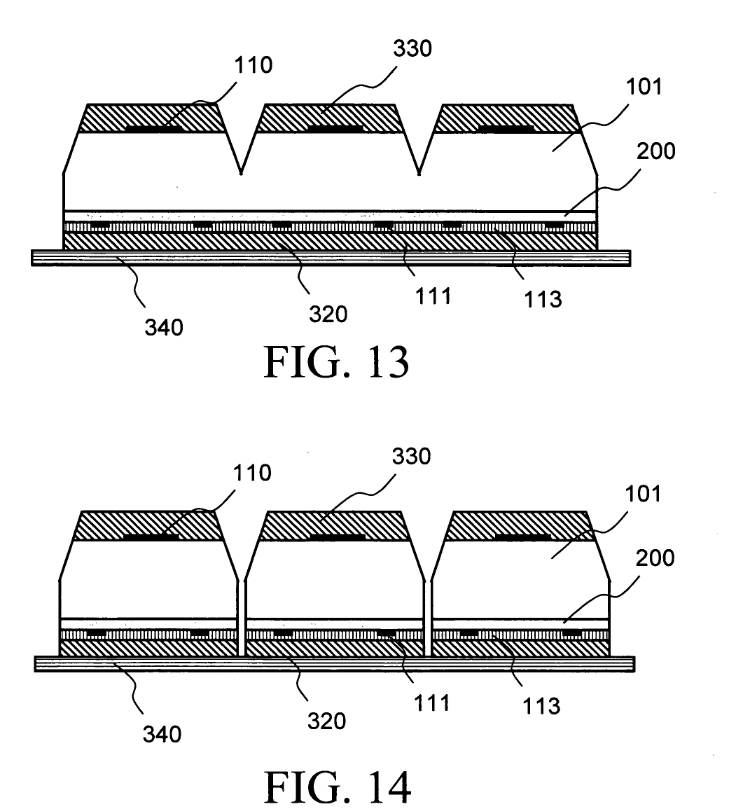

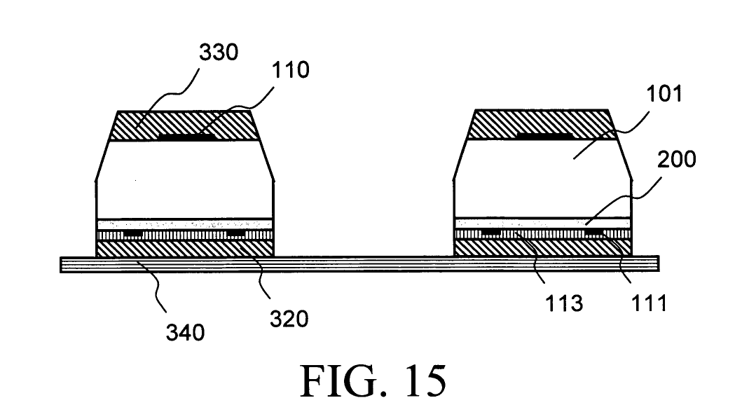

FIGS. 13 through 15 show the steps of manufacturing such light emitting diode. FIG. 13 is a cross-sectional view of the wafer. The both surfaces of the wafer are covered with the photo resist 320 and 330, and bonded to the tape 340. A blade having an appropriate edge angle is used for a first dicing. The first dicing is stopped before a full cut, as shown in FIG. 13.

Next a second dicing is carried out by using a thin blade with a perpendicular edge cross-section, as shown in FIG. 14. Subsequently The chips can be separated by expanding horizontally and the damage layer caused by the dicing is removed by etching on the side surface of the GaP substrate and the semiconductor multi-layer. The light emitting diode which includes the tapered surface and perpendicular side surface of the GaP substrate has the excellent light extraction efficiency minimizing the light absorption.

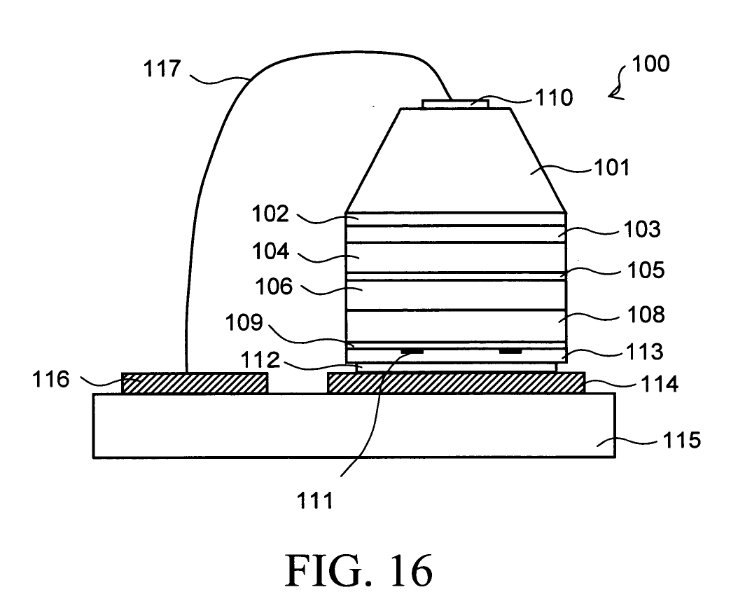

The light emitting device will be now described hereinafter. FIG. 16 is a subassembly of the device. This subassembly comprises an assembling substrate which provides an n-side electrode 114 and a p-side electrode 116, and a light emitting diode 100 mounted on the n-side electrode. Alight emitting diode 100 is described in the first embodiment of FIGS. 1 through 15. The diode may be mounted by the solder 112 or a conductive adhesion bond. The die bonding using the metal solder is desirable considering a heat radiation and a high temperature operation. A p-side electrode is connected with the p-side electrode 116 on the assembling substrate by wire bonding. The advantage of the above-mentioned structure is the improved heat radiation from the emitting region and the stable higher optical output because the light emitting multi-layer of InGaAlP can be mounted on the assembling substrate directly.

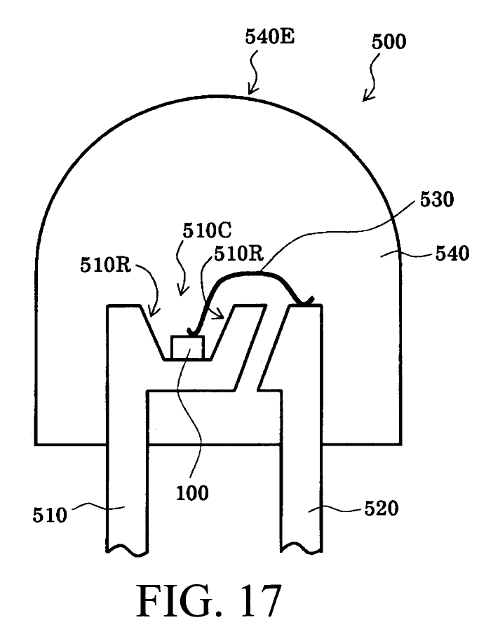

FIG. 17 is a light emitting device according to a second embodiment of the invention. This device is encapsulated in the epoxy resin and has an “artillery shell” shape. The light emitting diode 100 is mounted on the top portion of a lead frame 510 by using the adhesion bond and a p-side electrode is connected with the top portion of the other lead frame 520 by a bonding wire 530. The top portion of the lead frame 510 has a tapered inner surface 51OR which reflects the light upward. A cap portion 510C is formed by the transparent epoxy resin 540 and the top portion of the cap forms a curvature for collecting a light. In this embodiment the higher intensity is obtained due to the reflection by the tapered inner surface 510R.

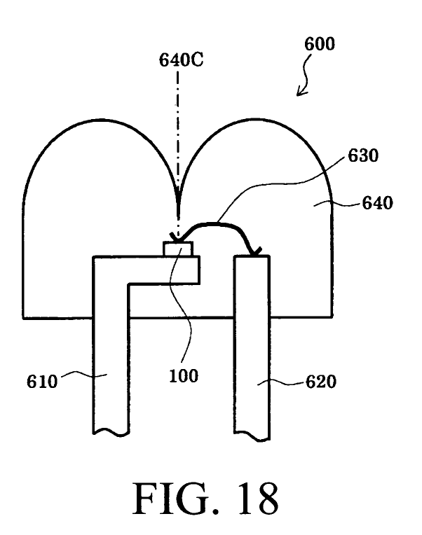

FIG. 18 is a light emitting device according to a third embodiment. The light emitting diode 100 is mounted on the top portion of a lead frame 610 and a p-side electrode is connected with the top portion of the other lead frame 620 by a bonding wire 630. Since an epoxy resin 640 has a shape of a rotation symmetry around an axis 640C and a concave shape in a central portion, the wider angle of emission of the light can be obtained. In this embodiment a transmitted light from the tapered surface 101S of the light emitting diode can be extracted effectively.

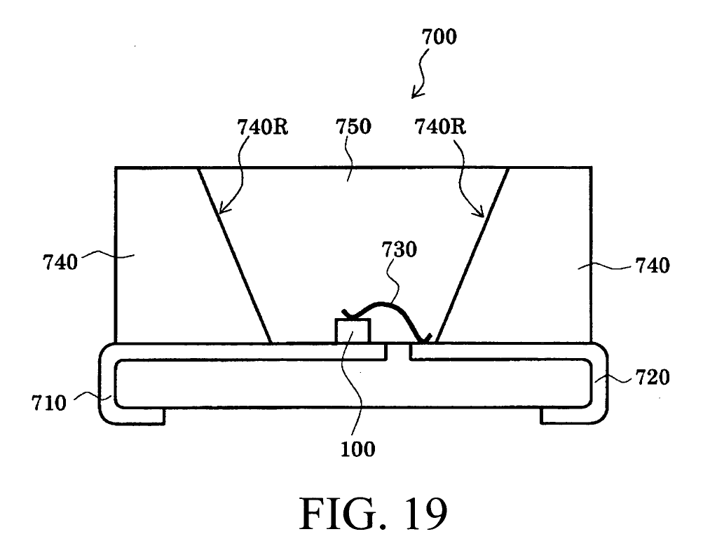

FIG. 19 is a light emitting device according to a fourth embodiment. This is called surface mounted type. The light emitting diode 100 is mounted on the lead farme 710 and a p-side electrode is connected with the other lead frame 720 by a bonding wire 730. These lead frames are buried with a first epoxy resin 740 except the chip region. The light emitting diode chip 100 is buried with a transparent epoxy resin. If fine particles such as oxide titanium are mixed in the first resin, the light is reflected on the surface 740R of the first resin and hence the higher intensity is obtained.

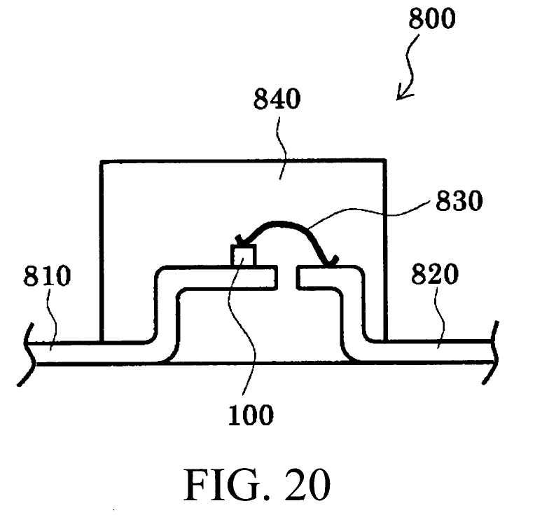

FIG. 20 is a modified device of the fourth embodiment. This device is also a surface mounted type. The light emitting diode 100 is mounted on the lead frame 810 and a p-side electrode is connected with the other lead frame 820 by a bonding wire 830. These are buried with a transparent epoxy resin 840.

In above embodiments an n-side ohmic metal has a hollow square shape. However the configuration is not restricted to this, but may be another such as a ring, a hollow ellipse, a hollow polygon and so on.

Additional advantages and modifications will readily occur to those skilled in the art. More specifically a various kinds of structures such as a double hetero junction and MQW, materials, and device shapes can be used.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

1. A semiconductor light emitting diode comprising:
a GaP substrate having a first and a second major surfaces;
a light emitting layer of InGaAlP provided on the first major surface of the substrate;
a contact layer provided on the light emitting layer;
an ohmic electrode selectively provided on the contact layer; and
a light reflecting metal layer which covers the ohmic first electrode and the contact layer.

2. The semiconductor light emitting diode according to claim 1, wherein the ohmic electrode is formed into a loop and an outer edge of the ohmic electrode is apart from an edge of the semiconductor light emitting diode.

3. The semiconductor light emitting diode according to claim 2, wherein a planar shape of the light emitting layer is substantially rectangular or square, and the ohmic electrode is formed into a rectangular loop or a square loop.

4. The semiconductor light emitting diode according to claim 1, wherein an alloyed region is formed at an interface between the ohmic electrode and the contact layer.

5. The semiconductor light emitting diode according to claim 1, wherein an alloyed layer is substantially not formed at an interface between the contact layer and the light reflecting metal layer.

6. The semiconductor light emitting diode according to claim 1, wherein a reflection coefficient of the light reflecting metal layer is higher than a light reflection coefficient of the ohmic electrode.

7. The semiconductor light emitting diode according to claim 1, further comprising a second electrode provided on the second major surface of the GaP substrate, an area of the second electrode is smaller than an area of the light emitting layer.

8. A semiconductor light emitting diode according to claim 7, wherein the ohmic electrode is provided in an outer region of the second electrode when seen along a direction perpendicular to the first or second major surface of the GaP substrate.

9. The semiconductor light emitting diode according to claim 1, wherein a side surface of the GaP substrate has a taper portion widening toward the light emitting layer.

10. The semiconductor light emitting diode according to claim 1, wherein a conductivity of the Gap substrate is p-type and a conductivity of the contact layer is n-type.

11. A semiconductor light emitting diode comprising:
a substrate having a first and a second major surfaces, the substrate being substantially transparent in a first wavelength range;
a light emitting layer provided on the first major surface of the substrate, the light emitting layer emitting a light of the first wavelength range;
a contact layer provided on the light emitting layer;
an ohmic electrode selectively provided on the contact layer; and
a light reflecting metal layer which covers the ohmic first electrode and the contact layer.

12. The semiconductor light emitting diode according to claim 11, wherein the ohmic electrode is formed into a loop and an outer edge of the ohmic electrode is apart from an edge of the semiconductor light emitting diode.

13. The semiconductor light emitting diode according to claim 12, wherein a planar shape of the light emitting layer is substantially rectangular or square, and the ohmic electrode is formed into a rectangular loop or a square loop.

14. The semiconductor light emitting diode according to claim 11, wherein an alloyed region is formed at an interface between the ohmic electrode and the contact layer.

15. The semiconductor light emitting diode according to claim 11, wherein an alloyed layer is substantially not formed at an interface between the contact layer and the light reflecting metal layer.

16. The semiconductor light emitting diode according to claim 11, wherein a reflection coefficient of the light reflecting metal layer is higher than a light reflection coefficient of the ohmic electrode.

17. The semiconductor light emitting diode according to claim 1, further comprising a second electrode provided on the second major surface of the substrate, an area of the second electrode is smaller than an area of the light emitting layer.

18. A semiconductor light emitting diode according to claim 17, wherein the ohmic electrode is provided in an outer region of the second electrode when seen along a direction perpendicular to the first or second major surface of the substrate.

19. The semiconductor light emitting diode according to claim 11, wherein a side surface of the substrate has a taper portion widening toward the light emitting layer.

20. A semiconductor light emitting device comprising:
a GaP substrate having a first and a second major surfaces;
a light emitting layer of InGaAlP provided on the first major surface of the substrate;
a contact layer provided on the light emitting layer;
an ohmic electrode selectively provided on the contact layer;
a light reflecting metal layer which covers the ohmic first electrode and the contact layer;
a first lead frame on which the light reflecting metal layer is mounted; and
a second lead frame with which the second electrode is connected by a bonding wire.
